(19) United States
(12) Patent Application Publication
(10) Pub. No.: US 2009/0126796 A1
(43) Pub. Date: May 21, 2009

(54) Highly Efficient Polymer Solar Cell by Polymer Self-Organization

(75) Inventors: Yang Yang, Los Angeles, CA (US); Gang Li, Los Angeles, CA (US)

Correspondence Address: VENABLE LLP, P.O. BOX 34385, WASHINGTON, DC, 20043-9998, US

(73) Assignee: The Regents of the University of California, Oakland, CA (US)

(21) Appl. No.: 11/887,938

(22) PCT Filed: Apr. 6, 2006
(86) PCT No.: PCT/US2006/012719

§ 371 Date: Jan. 8, 2009

Related U.S. Application Data
(60) Provisional application No. 60/669,332, filed on Apr. 7, 2005.

(51) Int. Cl. H01L 31/04; B05D 5/12; H01L 31/02

(52) U.S. Cl. 136/263; 427/74; 252/62.2

(57) ABSTRACT

A method of manufacturing a polymer composite film for an active layer of a photovoltaic cell according to an embodiment of this invention includes providing a quantity of a solution of a polymer matrix material, mixing a quantity of a guest material with the quantity of the solution of polymer matrix material to form a blend of active material, and controlling a growth rate of the polymer composite film to control an amount of self-organization of polymer chains in the polymer matrix material. A polymer composite film for an active layer of a photovoltaic cell is produced according to this method.

### CROSS-REFERENCE OF RELATED APPLICATION

This application claims priority to U.S. Provisional Application No. 60/669,332 filed Apr. 7, 2005, the entire contents of which are hereby incorporated by reference.

The U.S. Government has a paid-up license in this invention and the right in limited circumstances to require the patent owner to license others on reasonable terms as provided for by the terms of ONR Contract/Grant No. N00014-01-1-0136 and AFOSR Contract/Grant No. F49620-03-1-0101.

### BACKGROUND

1. Field of Invention

This application relates to methods of producing polymer composite films for photovoltaic cells, methods of producing photovoltaic cells and photovoltaic cells and polymer composite films produced thereby.

2. Discussion of Related Art

The contents of all references, including articles, published patent applications and patents referred to anywhere in this specification are hereby incorporated by reference.

Plastic solar cells have recently evolved as a promising cost effective alternative to silicon-based solar cells (Brabec, C. J., Sariciftci, N. S. & Hummelen, J., Adv. Func. Abater. 11, 15 (2001); K. M. Coakley and M. D. McGehee, Chem. Mater. 16, 4533 (2004); C. J Brabec, Sol. Ener. Mater. & Sol. Cells 83, 273 (2004)). However, low efficiencies (3-4%) of these plastic solar cells limit their feasibility for commercial use (S. E. Shaheen, C. J. Brabec, N. S. Saricifici, F. Padinger, T. Fromhertz, J. C. Hummelen, Appl. Phys. Lett. 78, 841 (2001); F. Padinger, R. S. Rittberger and N. S. Saraciftci, Adv. Func. Mater. 13, 85 (2003); C. Walduf, P. Schilinsky, J. Hauch and C. J. Brabec, Thin Solid Films 451-452, 503 (2004)). The efficiencies of polymer photovoltaic cells got a major boost with the introduction of the bulk heterojunction (BHJ) concept. (See G. Yu, J. Gao, J. C. Hummelen, F. Wudl, A. J. Heeger, Science 270, 1789 (1995) and N. S. Saraciftci, L. Smilowitz, A. J. Heeger, F. Wudl,Science 285, 1474 (1992).) BHJ structures have an interpenetrating network of electron donor and acceptor materials, and provide efficient charge separation because of large interface areas. This concept recently has also been successfully demonstrated in small-molecular organic photovoltaics (P. Peumans, S. Uchida, and S. R. Forrest, Nature 425, 158 (2003)). It is argued that due to the space charge effects inherent in the BHJ structure, the fill factor is usually low and the disordered structure will be ultimately limited by high series resistance (F. Yang, M. Shtein and S. Forrest, Nature Materials 4, 37 (2005)). To achieve a highly efficient photovoltaic (PV) device, solar radiation needs to be efficiently absorbed, for which the device thickness needs to be increased. However, this will further increase the series resistance. There is thus a need for improved polymer PV cells.

### SUMMARY

Further objectives and advantages will become apparent from a consideration of the description, drawings, and examples.

A method of manufacturing a polymer composite film for an active layer of a photovoltaic cell according to an embodiment of this invention includes providing a quantity of a solution of a polymer matrix material, mixing a quantity of a guest material with the quantity of the solution of polymer matrix material to form a blend of active material, and controlling a growth rate of the polymer composite film to control an amount of self-organization of polymer chains in the polymer matrix material. A polymer composite film for an active layer of a photovoltaic cell is produced according to an embodiment of this invention by this method.

A method of manufacturing a photovoltaic cell according to an embodiment of this invention includes providing a first electrode, providing a second electrode proximate the first electrode with a space reserved therebetween, and providing an active layer in at least a portion of the space reserved between the first electrode and the second electrode. The active layer is a polymer composite film manufactured according to a method of production that includes providing a quantity of a solution of a polymer matrix material, mixing a quantity of a guest material with the quantity of the solution of polymer matrix material to form a blend of active material, and controlling a growth rate of the polymer composite film to control an amount of self-organization of polymer chains in the polymer matrix material. A photovoltaic cell is produced according to an embodiment of this invention by this method.

A photovoltaic cell according to an embodiment of this invention has a first electrode, a second electrode proximate the first electrode with a space reserved therebetween, and an active layer disposed in at least a portion of the space reserved between the first electrode and the second electrode. The active layer is a polymer composite film and the photovoltaic cell according to this embodiment of the invention has a power conversion efficiency of at least about 4.4%, which can be enhanced with better materials available in the future.

### BRIEF DESCRIPTION OF THE DRAWINGS

The invention is better understood by reading the following detailed description with reference to the accompanying figures in which:

FIG. 1 shows UV-vis optical density vs. wavelength for six films formed by spin-coating from 1:1 wt-ratio RR-P3HT:PCBM solution in dichlorobenzene (thickness ˜100 nm) with the only difference being the spin-coating time (tₛₚᵢₙ);

FIG. 2a shows effects of thermal annealing on the performance of plastic solar cells according to an embodiment of the current invention;

FIG. 2b shows effects of film growth rate on the performance of the PV devices according to an embodiment of the current invention;

FIG. 3 shows the results of external quantum efficiency (EQE) measurements for tvo types of devices, slow grown (#1) and fast grown (#7);

FIG. 4 shows effects of film growth rate on the mobility of charge carriers in the active layer according to an embodiment of the current invention;

FIG. 5 shows effects of film growth rate and thermal annealing on the absorbance of the P3HT:PCBM films according to an embodiment of the current invention;

FIGS. 6a-6d show effects of growth rate and thermal annealing on the morphology of the active layer according to an embodiment of the current invention; and

FIG. 7 shows Table 1 summarizing properties of several devices produced according to embodiments of the current invention.

### DETAILED DESCRIPTION

In describing embodiments of the present invention illustrated in the drawings, specific terminology is employed for the sake of clarity. However, the invention is not intended to be limited to the specific terminology so selected. It is to be understood that each specific element includes all technical equivalents which operate in a similar manner to accomplish a similar purpose.

According to an embodiment of the current invention, a method to produce 15 polymer composite thin films is provided in which the growth rate of the films during solidification from the liquid phase is controlled. A polymer composite has p-type and n-type materials, one of which is a polymer and the other one can be a polymer, inorganic or organic molecules, nanocrystals, or C60 bulkyballs and its derivatives. The two components are blended in a proper ratio to achieve a nano-scaled phase separation where each phase forms an interpenetrating 3-D continuous network with the other phase.

By slowing the growth rate of the film, the alignment of the polymer chains can be enhanced resulting in an increased level of structural ordering in the composite structure. This ordering is induced because of self organization of polymer chains during slow growth of the film, allowing more time for the chains to align. When conducting conjugated polymers, such as poly(3-alkylthiophenes), are chosen as one of the components in the composite films, the higher degree of ordering or self organization can result in high carrier mobility for the charge carriers present on one or both components of the polymer composite film. As a result such polymer composite films can be used in electronic applications where high carrier mobility is required, such as polymer bulk heterojunction photovoltaic cells, polymer thin film transistors, etc. Increased mobility in thin polymer composite films can provide high-efficiency photovoltaic cells because of better charge transport and reduced loss due to recombination.

Such polymer composite films for these applications would have a polymer matrix as the host and a guest material. The guest materials can be a single compound, or can be a blend of two or more components, any one of which can be a polymer, inorganic or organic molecules, nanocrystals, or C60 and its derivatives. The alignment of polymer chains during slow growth is a property of the host polymer matrix, so it is selected to be a material which shows self organization upon slow growth. The guest materials should not destroy the ordering in the matrix completely, should be chemically inert with respect to the matrix material, and should form nano-scale phase separation upon blending.

According to an aspect of the current invention, the series resistance of polymer BHJ PV cells can be significantly reduced by polymer self-organization. As a result, we have achieved device power conversion efficiency of 4.4% (calibrated by National Renewable Energy Laboratory) under Standard reference condition (AM1.5 G, 100 mW/cm² 1-Sun illumination, 25° C.) according to an embodiment of this invention.

With good solvent of both donor (e.g. polymer) and acceptor (e.g. methenofullerene, quantum dots), three major parameters can be adjusted to achieve slow growth films with various film thicknesses and film growth rates:

1. Material concentrations in solution

2. Boiling point of solvent

3. Spin speed and time

Solvent mixing provides a practical way to fine tune film growth patterns and film morphology. In particular

1. By blending good solvent for both donor and acceptor with different boiling points (b.p.), the film growth pattern and morphology can be fine-tuned by adjusting the relative ratio of these solvents.

2. Blending solvents of different b.p. as well as solubility of one or both components of the donor/acceptor blend can additionally permit fine-tuning of donor/acceptor loading in different positions inside the active layer. This method may be significant in improving device open-circuit voltage which is one of the most limiting factors towards obtaining efficiency enhancement of polymer solar cells.

Several methods according to the current invention can provide a wide range of tuning of film morphology, thickness and film growth pattern for slow grown film for polymer solar cells. Due to reduced absorption in transparent versions, these cells can be stacked to provide either enhanced J_{sc} or V_{oc} for efficiency enhancing. Moreover, polymer solar cells with different spectral response can be manufactured separately and integrated in stacked configurations.

The methods of obtaining polymer self-organization described in the particular examples herein utilize spin coating techniques. This provides a convenient method to obtain uniform films in the laboratory; however, this invention is not limited to only spin coating techniques. Other methods may be used without departing from the general concepts of this invention. For example polymer self-organization can also be obtained by doctor blading, bar-coating, spray and other fabrication methods.

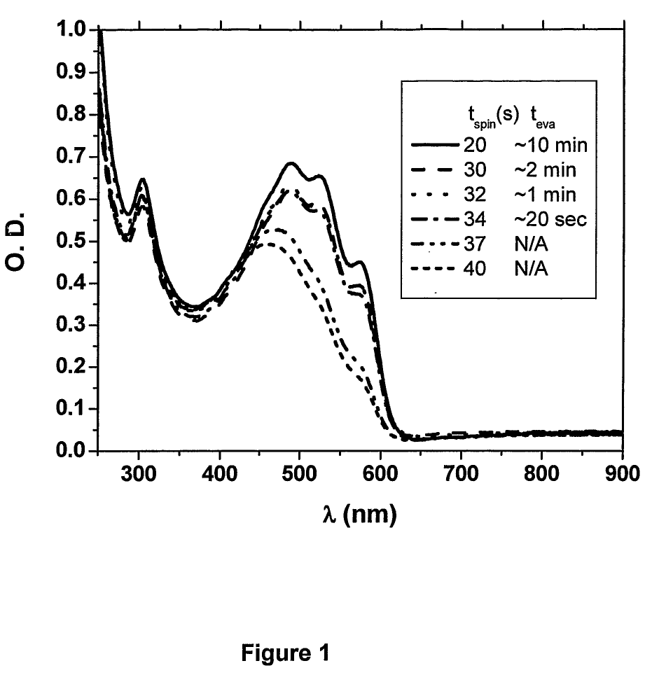

We have found that a majority of polymer self-organization can be completed in a film growth time scale of 20 seconds to 1 minute. (See FIG. 1 for an example.) FIG. 1 shows UV-vis optical density vs. wavelength for six films formed by spin-coating from 1:1 wt-ratio RR-P3HT:PCBM solution in dichlorobenzene (thickness ˜100 nm) with the only difference being the spin-coating time (tₛₚᵢₙ). The second column is the corresponding film growth time (or solvent evaporation time tₑᵥₐ). The clear vibronic features in the film with tₑᵥₐ of 20 seconds indicate that polymer ordering is largely maintained even in a film with 20 seconds growth time. Since intrinsically the polymer blend film is grown by solvent evaporation from liquid solution, this short film growth time indicates organic solvents with wide range of boiling points (eg., chloroform (62° C.), chlorobenzene (131° C.), dichlorobenzene (180° C.), trichlorobenzene (218° C.) can be utilized in large area fabrication of high efficiency polymer solar cells by polymer self-organization. Solvents with wide range of boiling point as well as their combination provide large freedom to fine tune polymer self-organization in real-world manufacturing processes.

### EXAMPLE 1

A polymer photovoltaic cell according to an embodiment of this invention has a polymer:fullerene blend for an active layer sandwiched betveen a transparent anode on glass (polyethylenedioxythiophene:polystyrenesulfonate (PEDOT:PSS) modified indium tin oxide) and a metal cathode (Ca (25 nm) capped with Al (100 nm) to protect from oxidation). A blend of regioregular poly(3-hexylthiophene) (RR-P3HT) and methanofullerene (PCBM) in 1:1 wt-ratio was used as the active layer in this example. Before device fabrication, the ITO (˜150 nm)-coated glass substrates were cleaned by ultrasonic treatment in detergent, de-ionized water, acetone and isopropyl alcohol, sequentially. A thin layer (˜30 nm) of PEDOT:PSS (Baytron P VP Al 4083) was spin-coated to modify the ITO surface. After baking at 120° C. for I hour, the substrates were transferred inside a nitrogen filled glove box (<0.1 ppm O₂ & H₂O) . P3HT was first dissolved in 1,2-dichlorobenzene (DCB) to make 17 mg/ml solution, followed by blending with PCBM in 50% wt. ratio. The blend was stirred for ˜14 hours at 40° C. in the glove box. The active layer was obtained by spin-coating the blend at 600 rpm for 60s, and the thickness of film was ˜210 nm, as measured from Dektek profilometer. The films were wet after spin-coating and were then dried in covered glass petri dishes. Before cathode deposition, the films were thermally annealed at 110° C. for various times. Testing was done in N₂ under simulated AM1.5G irradiation (100 mW/cm²) using a xenon-lamp based solar simulator.

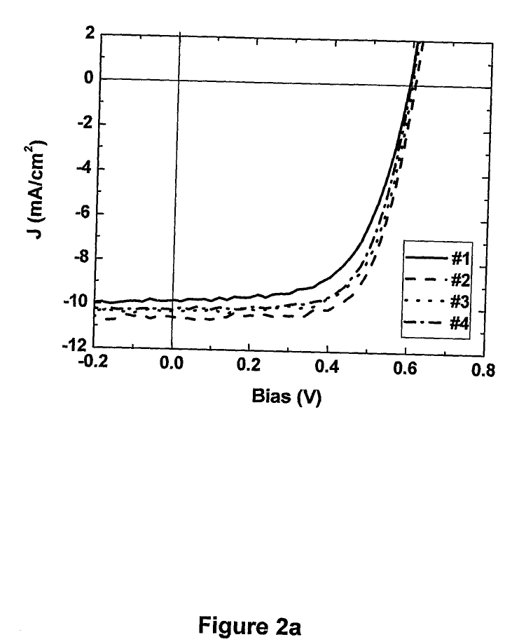

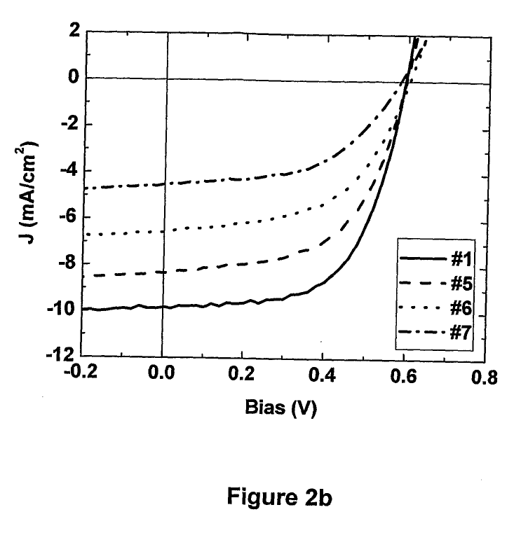

The current-voltage (J-V) curves under illumination for four devices with annealing times (t_{A}) of 0 (Device #1), 10 (#2), 20 (#3), and 30 min (#4) are shown in FIG. 2(a). The different J-V curves correspond to the devices with active layer before (#1), and afterthermal annealing at 110° C. for 10 min (#2), 20 min (#3), and 30 min (#4). The active layer thickness was ˜210 nm, and the film growth time was —20 minutes. Upon annealing, the short-circuit current (J_{SC}) increased slightly from 9.9 to 10.6 mA/cm² and the fill factor (FF) increased from 60.3% to 67.4%. As a result, the power conversion efficiency (PCE) improved from 3.5% to 4.4%. Under dark condition, the rectification ratios were close to 10⁷ at a bias of 2V for all four of the devices. The thickness of the active layer makes it free of pinholes and microcracks and all devices showed very high shunt resistance of 180-640 MΩ as derived from the J-V characteristics measured in dark. Based on 16 devices of the same kind (#2: t_{A}=10 min), the efficiency variation was 4.2+0.2%. Although, so far the highest reported polymer photovoltaic cell efficiency is for a P3HT:PCBM system in 1:2 wt-ratio, various independent studies have shown that 1:1 wt-ratio should be superior. (See D. Chirvas, J. Parisi, J. C. Hummelen and V. Dyakonov, Nanotechnology 15, 1317 (2004) and V. Shrotriya, J. Ouyang, R. J. Tseng, G. Li and Y. Yang, Chem. Phys. Lett., 411, 138 (2005.) It has also been reported that to absorb greater than 95% ofthe incident light over the range of 450-600 nm, 240 nm thick P3HT film is needed (K. M. Coakley and M. D. McGehee, Chem. Mater. 16, 4533 (2004)). With 1:1 P3HT:PCBM wt-ratio and the reflective cathode, 210 nm thick P3HT:PCBM film efficiently absorbs incident light. It is worth mentioning that the recently reported 3.85% P3HT:PCBM (1:2 wt-ratio) cell (C. Walduf, P. Schilinsky, J. Hauch and C. J. Brabec, Thin Solid Films 451-452, 503 (2004)) has an active layer thickness of 350 nm, indicating approximately the same amount of P3HT in the active layer. It is widely believed that the fundamental limitation ofthe photocurrent of polymer solar cells is because of the low mobility of holes in the donor polymer (C. J Brabec, Sol. Ener. Mater. & SoL Cells 83, 273 (2004)). Compared to the 3.85% cell, P3HT:PCBM network transports holes more efficiently in a 1:1 ratio, resulting in a more balanced electron and hole transport. Time-of-flight (TOF) measurements on P3HT:PCBM blend films with different wt-ratios verified that only 1:1 wt-ratio film gives balanced, non-dispersive electron and hole transport (J. Huang, G. Li and Y. Yang, Appl. Phys. Lett., 87, 112105 (2005)). The much improved FF of 67.4% for devices with 1:1 wt-ratio vs. 47% for 1:2 wt-ratio also supports this argument (S. E. Shaheen, C. J. Brabec, N. S. Saricifici, F. Padinger, T. Fromhertz, J. C. Hummelen, Appl. Phys. Lett. 78, 841 (2001)).

The highly regular chain structure ofpoly(3-alkylthiophene)s (P3ATs) facilitates their self-organization into two-dimensional sheets via interchain stacking (B. Grevin, P. Rannou, R. Payerne, A. Pron, and J. P. Travers, J Chem Phys. 118, 7093 (2003)). Self-organization has been shown to improve field-effect carrier mobility in RR-P3HT by over 100 times to 0.1 cm²/V-s (H. Sirringhaus, P. J. Brown, R. H. Friend, M. M. Nielsen, K. Bechgaard, B. M. W. Langeveld-Voss, A. J. H. Spiering, R. A. J. Janssen, E. W. Meijer, P. Herwig & D. M. de Leeuw, Nature 401, 685 (1999); Z. Bao, A. Dodabalapur, A. J. Lovinger, Appl.. Phys. Lett. 69, 4108 (1996)). The slow growth will assist the formation of self-organized ordered structure in the P3HT:PCBM blend system. The degree ofself-organization can be varied by controlling the film growth rate, or in other words, by controlling the time it takes for the wet films to solidify.

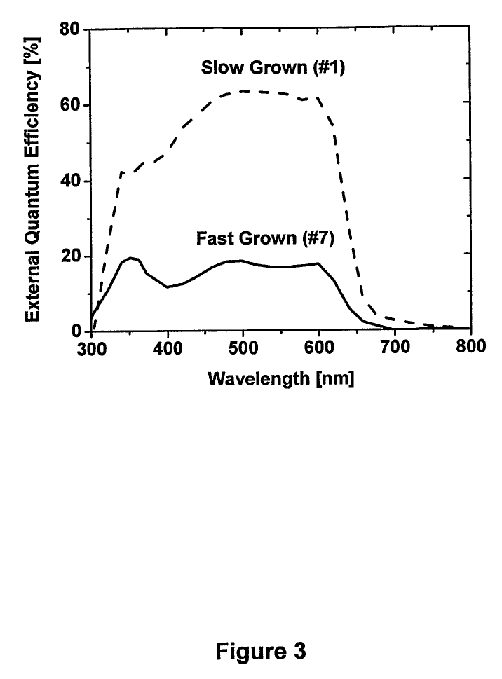

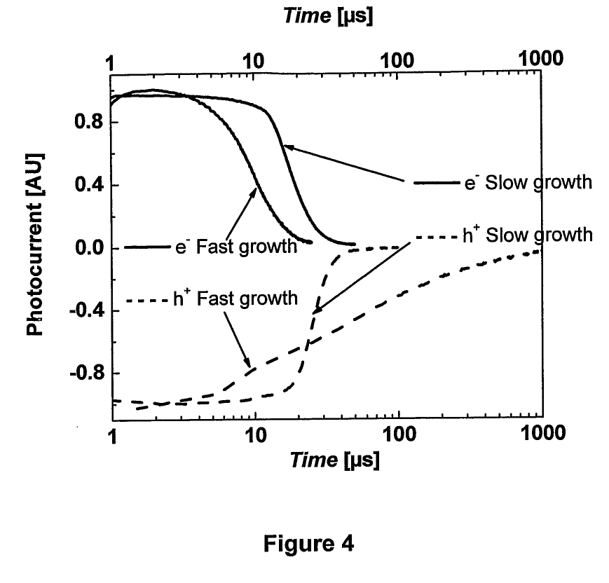

In FIG. 2(b) we compare the J-V characteristics of four devices with different solvent evaporation times (tₑᵥₚ) after spin coating, judging by visual inspection of the change in film color when it solidifies from the liquid phase. Device #1 was covered in a glass petri dish while drying and had tₑᵥₚ ˜20 min, #5 was left open in N₂ ambient and had tₑᵥₚ 3 min, #6 and #7 were dried by putting them on a hot plate at 50° C. and 70° C., respectively, and had tₑᵥₚ ˜40 s and ˜20 s. The J_{SC} reduced from 9.9 to 8.3, 6.6, and 4.5 mA/cm², and the device series resistance, R_{SA}, increased from 2.4 to 4.5, 12.5, and, 19.8 Ωcm² with reducing tₑᵥₚ. Series and shunt resistances were derived from the slope ofthe I-V characteristic curve under dark condition close to 2V and 0V, respectively. See F. Shirland, Adv. Energy Conversion 6, 201 (1966). The FF also consistently decreased from 60.3% to 52.0%. The low RSA of 2.4 Ωcm² achieved is comparable to that of a much thinner device (˜48 nm), underlining the effect of self-organization (G. Li, V. Shrotriya, Yan Yao and Y. Yang, J. Appl. Phys., 98, 043704 (2005)). FIG. 3 shows the results of external quantum efficiency (EQE) measurements for two types of devices, slow grown (#1) and fast grown (#7). The EQE for the device with fast grown film shows a maximum of ˜19% at a wavelength of 350 nm. On the other hand, for the device with slow grown film, the EQE maximum increases by more than three times to ˜63% at 500 nm. The integral of the product of this absolute EQE and the global reference spectrum yields a J_{SC} of 9.47 mA/cm² which matches closely to the J_{SC} that we measured for this particular device. This increase in quantum efficiency over the wavelength range of 350-650 nm contributes to the increase in the power conversion efficiency of our devices. We believe that this enhancement in EQE originates from twvo important contributions, an increase in the charge carrier mobility, and increased absorption in the active layer. The discussion on the effect of slow growth rate on the charge carrier mobility and the absorption spectra of the films follows. TOF study was conducted on slow (#1) and fast (#7) grown films at E ˜2×10⁵ V/cm. As can be clearly seen in FIG. 4, in film #1 both electron and hole transport non-dispersively with μₑ=7.7×10⁻⁵ and μₕ=5.1×10⁻⁵ cm² V-s, whereas for film #7, fast growth led to dispersive hole transport and significantly reduced μₕ to 5.1×10⁻⁶ cm²/V-s. Note that the hole mobility in film #7 is comparatively low and is represented by the upper scale in FIG. 4, whereas the other three curves are represented by the lower scale, as indicated by the arrows. The electron mobility increased slightly to 1.1×10⁻⁴ cm²/V-s. The unbalanced electron and hole transport and the significantly reduced hole mobility resulted in the reduced photocurrent and FF. The destruction of ordered structure during fast growth is believed to be the reason. The ratio between electron and hole mobilities is close to unity (μₑ/μₕ˜1.5), resulting in balanced carrier transport in the active layer. This balanced transport is believed to be the reason for high FF values and much better device performance. (See Mihailetchi, V. D. et al. Compositional dependence of the performance of poly(p-phenylenevinylene):methanofullerene bulk-heterojunction solar cells. Adv. Funct. Mater. 15, 795-801 (2005); Pacios, R., Nelson, J., Bradley, D. D. C. & Brabec, C. J. Composition dependence of electron and hole transport in polyfluorene:[6,6]-phenyl C₆₁-butyric acid methyl ester blend films. Appl. Phys. Lett. 83, 4764-4766 (2003).) On the other hand, for the fast grown film the unbalanced electron and hole transport and the significantly reduced hole mobility resulted in low photocurrent and poor FF.

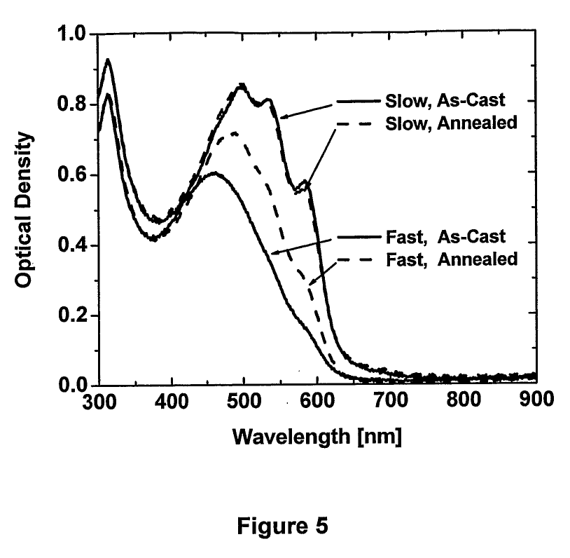

The absorption spectra of#1 and #7 films are shown in FIG. 5, before and after thermal annealing at 110° C. for 20 minutes. The spectra were taken using a Varian Cary 50 UV-Visible Spectrophotometer. To mimic the device fabrication conditions, all the films were spun-cast on PEDOT:PSS covered silica glass, also used as the absorption baseline. Compared to the film dried at 70° C. (#7), the absorption in the red region of the slow grown film (#1) was much stronger. The three vibronic absorption shoulders were more pronounced in film #1, indicating a higher degree of ordering (M. Sunderberg, O. Inganas, S. Stafstrom, G. Gustafsson and B. Sjogren,Solid State Communin ications 71, 435 (1989)). After annealing at 110° C. for 20 minutes, the absorbance of film #7 showed significant increment and the vibronic features became clearer, indicating a partial recovery of ordering. During the fast growth of the film, the orientation of P3HT supermolecules is forced by the short time scale and is not thermodynamically stable. On thermal annealing the chains become mobile and self-organization can occur to form ordering. Significant red-shift appeared in the more ordered films since high crystalline order involves an enhanced conjugation length and hence a shift of the absorption spectrum to lower energies (M. Sunderberg, O. Inganas, S. Stafstrom, G. Gustafsson and B. Sjogren, Solid State Communications 71, 435 (1989)). For the slow grown film #1, the absorption spectra showed no difference before and after thermal annealing, further strengthening our conclusion that the slow grown film already has a high degree of ordering.

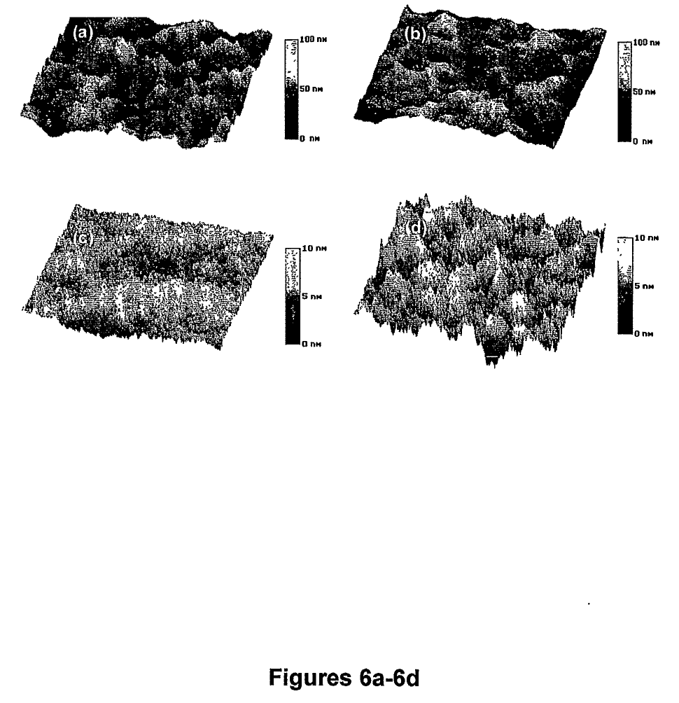

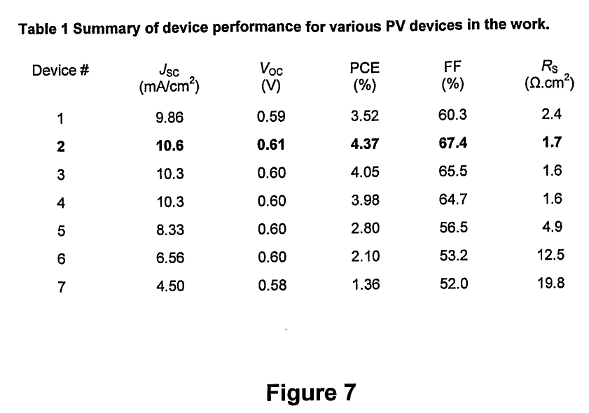

FIGS. 6a-6d show the atomic force microscopy (AFM) images ofthe as-cast and annealed films #1 and #7. The AFM height images of the P3HT:PCBM composite films (PCBM conc.=50 wt. %) show 5 μm×5 μm surface areas. The different images represent: (5a) slow grown (#1) film before thermal annealing, and, (5b) after thermal annealing at 110 ° C. for 10 minutes; (5c) fast grown film (#7) before thermal annealing, and, (5d) after thermal annealing at 110° C. for 20 minutes. Note that the scale for the films (5a) and (5b) is 0-100 nm, whereas for films (5c) and (5d) is 0-10 nm. For film #1, the surface was very rough with root-mean-square (rms) roughness, σ, of 11.5 nm (FIG. 6a), which is ˜10 times higher than that of thin film (˜48 nm: σ˜1 nm). After 10 minutes of annealing at 110° C., the film showed a similar a σ˜9.5 nm (FIG. 6b). For film #7, a very smooth surface with σ˜0.87 nm was observed (FIG. 6c). Upon heating at 110° C. for 20 minutes, the roughness increased with σ˜1.9 nm (FIG. 6d). By comparing these results with device performance, we first suspected that the rough surface may effectively reduce the charge transport distance and increase the J_{SC}, at the same time providing nano-scaled texture which further enhances internal light scattering and light absorption. However, using the surface area calculation function in our AFM program, the surface area in the roughest film was found to be only 0.4% more than that of an absolutely flat film. Thus, these mechanisms can only account for minor efficiency improvement at most. Instead, the rough surface is most likely a signature of polymer (blend) self-organization which in turn enhances ordered structure formation in the thin film. This assumption is strongly supported by: a) very rough surface of slow-grown thick film; b) significant roughness increment after annealing of fast-grown thick film; and c) roughness increment after annealing of thin films (G. Li, V. Shrotriya, Yan Yao and Y. Yang, J. Appl. Phys., 98, 043704 (2005)), all of which significantly enhance device efficiency. The peak-to-valley height of the slow grown film is ˜100 nm, corresponding to ˜50% of the mean thickness. This naturally formed rough surface structure also holds the potential to form controlled BHJ structure when using P3HT instead of the blend (F. Yang, M. Shtein and S. Forrest, Nature Materials 4, 37 (2005)). Thermal annealing of P3AT films has been shown to enhance crystallization and increase the hole mobility as observed in TFTs (F. Yang, M. Shtein and S. Forrest, Nature Materials 4, 37 (2005); D. Chirvas, J. Parisi, J. C. Hummelen and V. Dyakonov, Nanotechnology 15, 1317 (2004)) and photovoltaic cells (F. Padinger, R. S. Rittberger and N. S. Saraciftci, Adv. Func. Mater. 13, 85 (2003)). However, this might not be true for well-ordered thicker films such as the ones in our case, as seen from the absorption spectra and no significant increase in Jsc upon annealing. We observed that both Jsc and FF tended to increase when devices were left in the vacuum for a long time. Thus we suspect annealing the slow grown films might mainly help in removing the solvent residue, reducing the free volume and improving the interface with the electrode, instead of inducing further self-organization in already ordered films. As a result of annealing, the number of trapping sites is reduced for carrier transport and extraction. Annealing at 110° C. reduces R_{SA} from 2.41 to 1.56 Ω.cm², which is among the lowest values reported for similar device dimensions (J. Xue, S. Uchida, B. P. Rand and S. R. Forrest, Appl. Phys. Lett. 84, 3031 (2004)). Along with a better balanced charge transport this gives a very high FF of 67.4% and the PCE of 4.4%. Properties of several devices produced according to embodiments of the current invention are summarized in Table I contained in FIG. 7.

In this example, we have fabricated polymer photovoltaic cells utilizing a thick active layer with power conversion efficiency of 4.4%. The self-organization of polymer chains during the slow film growth from liquid phase, enhanced light absorption due to the film thickness, and the rough interface are believed to be mainly responsible for the high device efficiency. The efficiency value reported here is the highest ever reported for polymer BHJ PV cells to the best of our knowledge, and the efficiency can be enhanced with better materials available in the future.

### EXAMPLE 2

In this example 20 ml/mg P3HT and 20 mg/ml PCBM in 1,2-dichlorobenzene (DCB) (m.p. -17° C., bp 180° C.) solution was used. A spin speed of 600 rpm for 60 seconds was used and a slow growth film of ˜210 nm was achieved. The power conversion efficiency (PCE) under standard AM1.5 G 1-sun testing condition was found to be up to about 4.4%.

### EXAMPLE 3

In this example the same solution as Example 2 is used, but a spin speed of 3000 rpm is used. This reduces the spin-coating time tₛto 5-10 seconds. Slow growth film devices with ˜70 nm were achieved. AM1.5 G PCE of 3.0% was achieved in a tₛ=5 sec device (film grown time ˜10 min) with fill-factor of 69.2%. The tₛ=10 sec device has film grown time of ˜2 min and PCE of 2.8% (FF 66%). Reduced film growth time might be advantageous for some applications. Spin coating over 20 seconds at 3 k rpm can eliminate slow growth pattern.

### EXAMPLE 4

With solvents of higher boiling point (same material concentration), thinner slow growth devices can be achieved under similar spin time but faster spin speed. For example, the following solvents may be suitable in various applications: chloroform (62° C.), chlorobenzene (131° C.), dichlorobenzene (180° C.), trichlorobenzene (218° C. ). (The corresponding boiling points are noted in parentheses.) For example, using trichlorobenzene (bp 218° C.) solution of the same concentration and spin-coating 30 seconds at 3000 rpm (film growth ˜20 minutes), devices with 3.8% PCE (71% FF) have been achieved. In this example the active layer can be ˜70-80 nm.

### EXAMPLE 5

By using the same blend system with different concentrations in proper solvent, the same spin-coating conditions can provide films with various thicknesses but almost identical film growth condition.

By blending solvents with different boiling points (b.p.), the film growth pattern and morphology can be fine-tuned by adjusting the relative ratio of these solvents.

The embodiments illustrated and discussed in this specification are intended only to teach those skilled in the art the best way known to the inventors to make and use the invention. Nothing in this specification should be considered as limiting the scope of the present invention. The above-described embodiments of the invention may be modified or varied, and elements added or omitted, without departing from the invention, as appreciated by those skilled in the art in light of the above teachings. It is therefore to be understood that, within the scope of the claims and their equivalents, the invention may be practiced otherwise than as specifically described.

1. A method of manufacturing a polymer composite film for an active layer of a photovoltaic cell, comprising:
providing a quantity of a solution comprising a polymer matrix material;
mixing a quantity of a guest material with said quantity of said solution comprising said polymer matrix material to form a blend of active material; and
controlling a growth rate of said polymer composite film to control an amount of self-organization of polymer chains in said polymer matrix material.

2. A method of manufacturing a polymer composite film for an active layer of a photovoltaic cell according to claim 1, wherein said quantity of said solution comprising said polymer matrix material further comprises a solvent selected according to a boiling point of said solvent to control a growth rate of said polymer composite film.

3. A method of manufacturing a polymer composite film for an active layer of a photovoltaic cell according to claim 2, wherein said solvent comprises at least one of a trichlorobenzene and a diclorobenzene.

4. A method of manufacturing a polymer composite film for an active layer of a photovoltaic cell according to claim 1, further comprising spin coating said blend of active material onto a substrate,
wherein said controlling said growth rate of said polymer composite film comprises selecting at least one of a spin speed and a spin time of said spin coating said blend of active material.

5. A method of manufacturing a polymer composite film for an active layer of a photovoltaic cell according to claim 1, wherein said controlling said growth rate of said polymer composite film comprises selecting a concentration of said polymer matrix material relative to said guest material.

6. A method of manufacturing a polymer composite film for an active layer of a photovoltaic cell according to claim 1, wherein said polymer matrix material consists essentially of a regioregular poly (3-hexylthiophene) material.

7. A method of manufacturing a polymer composite film for an active layer of a photovoltaic cell according to claim 1, wherein said guest material comprises at least one of a polymer, inorganic molecules, organic molecules, nanocrystals and fullerenes.

8. A method of manufacturing a polymer composite film for an active layer of a photovoltaic cell according to claim 1, wherein said guest material comprises methanofullerene.

9. A method of manufacturing a polymer composite film for an active layer of a photovoltaic cell according to claim 6, wherein said guest material comprises methanofullerene.

10. A method of manufacturing a polymer composite film for an active layer of a photovoltaic cell according to claim 9, wherein said regioregular poly (3-hexylthiophene) and said methanofullerene form said blend of active material in a ratio of about 1 to 1 by weight.

11. A method of manufacturing a photovoltaic cell, comprising:
providing a first electrode;
providing a second electrode proximate said first electrode with a space reserved therebetween; and
providing an active layer in at least a portion of said space reserved between said first electrode and said second electrode,
wherein said active layer is a polymer composite film manufactured according to a method of production, comprising:
providing a quantity of a solution comprising a polymer matrix material;
mixing a quantity of a guest material with said quantity of said solution comprising said polymer matrix material to form a blend of active material; and
controlling a growth rate of said polymer composite film to control an amount of self-organization of polymer chains in said polymer matrix material.

12. A method of manufacturing a photovoltaic cell according to claim 11, further comprising disposing a second active layer in at least a portion of said space reserved between said first electrode and said second electrode,
wherein said second active layer is a polymer composite film manufactured according to a method of production, comprising:
providing a quantity of a solution comprising a polymer matrix material;
mixing a quantity of a guest material with said quantity of said solution comprising said polymer matrix material to form a blend of active material; and
controlling a growth rate of said polymer composite film to control an amount of self-organization of polymer chains in said polymer matrix material.

13. A method of manufacturing a photovoltaic cell according to claim 11, wherein at least one of said first and second electrodes is substantially transparent to light in a spectral range in which said active layer absorbs light to convert it into electrical power.

14. A method of manufacturing a photovoltaic cell according to claim 12, wherein at least one of said first and second electrodes is substantially transparent to light in a spectral range in which said first and second active layers absorb light to convert it into electrical power, and
wherein at least one of said first and second active layers allows light to pass therethrough that can be absorbed by the other one of said first and second active layers to provide an at least complementary light absorption to increase an overall power conversion efficiency.

15. A polymer composite film for an active layer of a photovoltaic cell produced according to the method of claim 1.

16. A photovoltaic cell produced according to the method of claim 11.

17. A photovoltaic cell, comprising:
a first electrode;
a second electrode proximate said first electrode with a space reserved therebetween; and
an active layer disposed in at least a portion of said space reserved between said first electrode and said second electrode,
wherein said active layer is a polymer composite film, and
wherein said photovoltaic cell has a power conversion efficiency of at least about 4.9%.
